(19) United States
(12) Patent Application Publication
(10) Pub. No.: US 2025/0365850 A1
(43) Pub. Date: Nov. 27, 2025

(54) ELECTRONIC DEVICE

(71) Applicants: FLOSFIA INC., Kyoto (JP); MITSUBISHI HEAVY INDUSTRIES, LTD., Tokyo (JP)

(72) Inventors: Daisuke ASA, Tokyo (JP); Masato ITO, Tokyo (JP); Shota OKUBO, Tokyo (JP); Masaya MITAKE, Tokyo (JP); Kengo TAKEUCHI, Kyoto (JP); Tatsuhiro NAKAZAWA, Kyoto (JP); Hiroshi KONDO, Kyoto (JP); Hirofumi KOMIYA, Kyoto (JP); Toshimi HITORA, Kyoto (JP)

(21) Appl. No.: 19/295,362

(22) Filed: Aug. 8, 2025

Related U.S. Application Data
(63) Continuation-in-part of application No. PCT/JP2024/004435, filed on Feb. 8, 2024.

(30) Foreign Application Priority Data
Feb. 9, 2023 (JP) 2023-018292

(51) Int. Cl. H05K 1/02; H02M 7/00; H02M 7/5387; H05K 1/14

(52) U.S. Cl. CPC H05K 1/0203; H02M 7/003; H02M 7/53871; H05K 1/141; H05K 1/144; H05K 2201/066; H05K 2201/10166; H05K 2201/10174

(57) ABSTRACT

Provided is an electronic device including, a module unit including a wiring substrate and a power element-embedded substrate mounted on the wiring substrate; and a mounting substrate, the module unit being mounted on the mounting substrate so that the wiring substrate is parallel to or substantially parallel to the mounting substrate, a heat dissipation member for thermally dissipating heat from the power element-embedded substrate being disposed on the power element-embedded substrate side of the wiring substrate.

### CROSS REFERENCE TO RELATED APPLICATION

This application is a continuation-in-part application of International Patent Application No. PCT/JP2024/004435 (Filed on Feb. 8, 2024), which claims the benefit of priority from Japanese Patent Application No. 2023-018292 (filed on Feb. 9, 2023).

The entire contents of the above applications, which the present application is based on, are incorporated herein by reference.

### 1. FIELD OF THE INVENTION

The present disclosure relates to an electronic device in which a composite module unit including a wiring substrate and a power element-embedded substrate is mounted on a mounting substrate.

### 2. DESCRIPTION OF THE RELATED ART

A power conversion device is known to include a first substrate, a second substrate longitudinally provided on the first substrate, an electronic component disposed on a surface on one side of the second substrate in a plate thickness direction, and a heat sink disposed along the second substrate on the one side.

It should be noted that the Background Art section is intended to provide embodiments of the present disclosure in a technical or operational context to aid those skilled in the art in understanding the scope and usefulness of the present disclosure. No description disclosed herein is considered prior art merely because it is included in the Background Art section unless it is expressly identified as such.

### SUMMARY OF THE INVENTION

The following presents a simplified summary of the disclosure, which is intended to provide a basic understanding to those skilled in the art. This summary is not intended to identify key elements of the embodiments disclosed herein or to delineate the scope thereof. This summary presents some of the concepts disclosed herein in a simplified form, which serves as a prelude to the more detailed description presented later.

According to an example of the present disclosure, there is provided an electronic device including, a module unit including a wiring substrate and a power element-embedded substrate mounted on the wiring substrate; and a mounting substrate, the module unit being mounted on the mounting substrate so that the wiring substrate is parallel to or substantially parallel to the mounting substrate, a heat dissipation member for thermally dissipating heat from the power element-embedded substrate being disposed on the power element-embedded substrate side of the wiring substrate.

According to an example of the present disclosure, there is provided an electronic device including, a first module unit including a first wiring substrate and a first power element-embedded substrate mounted on the first wiring substrate; a second module unit including a second wiring substrate and a second power element-embedded substrate mounted on the second wiring substrate; and a mounting substrate, the first module unit being mounted so that the first wiring substrate is parallel to or substantially parallel to the mounting substrate, the second module unit being stacked on the first module unit.

According to an example of the present disclosure, there is providedan electronic device including, a module unit including a wiring substrate, and a power element-embedded substrate and gate driver mounted on the wiring substrate; and a mounting substrate, the module unit being longitudinally provided on the mounting substrate, the power element-embedded substrate and the gate driver being disposed on a first surface side of the wiring substrate, a heat dissipation member for thermally dissipating heat from the power element-embedded substrate being disposed on the first surface side of the wiring substrate.

According to an example of the present disclosure, there is provided an electronic device including, a module unit including a wiring substrate, and a power element-embedded substrate and gate driver mounted on the wiring substrate; and a mounting substrate, the module unit being longitudinally provided on the mounting substrate, the power element-embedded substrate being disposed on a first surface side of the wiring substrate, the gate driver being disposed on a second surface side of the wiring substrate opposite to the first surface side.

Thus, the electronic device according to the present disclosure may be reduced in size.

### BRIEF DESCRIPTION OF THE DRAWINGS

FIG. 1 is an exploded perspective diagram schematically illustrating an electronic device according to a first embodiment.

FIG. 2 is a cross-sectional diagram schematically illustrating the electronic device according to the first embodiment.

FIG. 3 is an equivalent circuit diagram of a semiconductor circuit including a power element according to the first embodiment.

FIG. 4 is a cross-sectional diagram schematically illustrating an example of a power element-embedded substrate according to the first embodiment.

FIG. 5 is an exploded perspective diagram schematically illustrating an electronic device according to a second embodiment.

FIG. 6 is a cross-sectional diagram schematically illustrating the electronic device according to the second embodiment.

FIG. 7 is an exploded perspective diagram schematically illustrating an electronic device according to a third embodiment.

FIG. 8 is a cross-sectional diagram schematically illustrating the electronic device according to the third embodiment.

FIG. 9 is an exploded perspective diagram schematically illustrating an electronic device according to a fourth embodiment.

FIG. 10 is a cross-sectional diagram schematically illustrating the electronic device according to the fourth embodiment.

FIG. 11 is a block diagram illustrating an example of a control system applying an electronic device according to an embodiment of the disclosure.

FIG. 12 is a circuit diagram illustrating an example of the control system applying an electronic device according to an embodiment of the disclosure.

FIG. 13 is a block configuration diagram illustrating another example of the control system applying an electronic device according to an embodiment of the disclosure.

FIG. 14 is a circuit diagram illustrating another example of the control system applying an electronic device according to an embodiment of the disclosure.

FIG. 15 is a top view diagram schematically illustrating an electronic device according to a fifth embodiment.

FIG. 16A is a cross-sectional diagram taken along the lines A-A of FIG. 15, which schematically illustrates the electronic device according to the fifth embodiment.

FIG. 16B is a cross-sectional diagram taken along the lines B-B of FIG. 15, which schematically illustrates the electronic device according to the fifth embodiment.

FIG. 16C is a cross-sectional diagram taken along the lines C-C of FIG. 15, which schematically illustrates the electronic device according to the fifth embodiment.

FIG. 16D is a cross-sectional diagram taken along the lines D-D of FIG. 15, which schematically illustrates the electronic device according to the fifth embodiment.

FIG. 17 is an exploded perspective diagram schematically illustrating the electronic device according to the fifth embodiment.

FIG. 18 is a cross-sectional diagram schematically illustrating an electronic device according to a modified example 1.

FIG. 19 is an exploded perspective diagram schematically illustrating the electronic device according to the modified example 1.

FIG. 20 is a cross-sectional diagram schematically illustrating an electronic device according to a modified example 2.

FIG. 21 is an exploded perspective diagram schematically illustrating the electronic device according to the modified example 2.

### DETAILED DESCRIPTION

The aspects of the present disclosure and the various features and advantageous details thereof will be explained more fully with reference to the non-limiting aspects and examples described and/or illustrated in the accompanying drawings and detailed in the following description. It should be noted that the features illustrated in the drawings are not necessarily drawn to scale, as those skilled in the art would recognize, even if not explicitly stated herein. Also, it should be noted that one feature in one aspect may be employed alone or in combination with other features in other aspects. Descriptions of well-known components and processing techniques may be omitted so as to not unnecessarily obscure the aspects of the present disclosure. The examples used herein are intended merely to facilitate an understanding of ways in which the present disclosure may be practiced and to further enable those skilled in the art to practice the aspects of the present disclosure. Accordingly, the examples and aspects herein should not be construed as limiting the scope of the present disclosure, which is defined solely by the appended claims and the applicable law. Furthermore, similar reference numerals represent similar parts throughout the drawings disclosed herein.

The terms “first”, “second”, and the like may be used herein to describe various elements, but these elements should not be limited by these terms. These terms “first”, “second”, and the like are merely used to distinguish one element from another. For example, a first element may be termed a second element, and, similarly, a second element may be termed a first element, without departing from the scope of the present disclosure. As used herein, the term “and/or” includes any or all combinations of one or more of the associated listed items.

It should be understood that when an element such as a layer, region, or substrate is referred to as being “on” or extending “onto” another element, it may be directly on or extend directly onto the other element or an intervening element may also be present. In contrast, when an element is referred to as being “directly on” or extending “directly onto” another element, there is no intervening element present. Similarly, it should be understood that when an element such as a layer, region, or substrate is referred to as being “over” or extending “over” another element, it may be directly over or extend directly over the other element or an intervening element may also be present. In contrast, when an element is referred to as being “directly over” or extending “directly over” another element, there is no intervening element present. It should also be understood that when an element is referred to as being “connected” or “coupled” to another element, it may be directly connected or coupled to the other element or an intervening element may be present. In contrast, when an element is referred to as being “directly connected” or “directly coupled” to another element, there is no intervening element present. Furthermore, it should be understood that when an element is referred to as being “stacked” on another element, it may be directly stacked on the other element or an intervening element may be present. In contrast, when an element is referred to as being “directly stacked” on another element, there is no intervening element present.

The terminology used herein is for the purpose of describing particular aspects only and is not intended to be limiting of the present disclosure. It should be understood that the terms “comprise (or comprising)” or “include (or including)” specify the presence of stated elements, but do not preclude the presence of one or more other elements.

Unless otherwise defined, all terms (including technical and scientific terms) used herein have the same meaning as commonly understood by those skilled in the art to which the present disclosure belongs. Terms used herein should be interpreted as having a meaning that is consistent with their meaning in the context of this specification and the relevant art. It should be further understood that terms used herein should not be interpreted in an idealized or overly formal sense unless expressly defined so herein.

In the present disclosure, unless otherwise defined, a stacking direction of a wiring substrate (direction perpendicular to the wiring substrate surface) is described as the Y direction, and a stacking direction of a mounting substrate (direction perpendicular to the mounting substrate surface) is described as the Z direction. Moreover, in a module unit in which the power element-embedded substrate is mounted on a first surface side of the wiring substrate, “top (or upper or above)” is defined as an upper side which is the power element-embedded substrate side when viewed from the wiring substrate, and “bottom (or lower or below)” is defined as the lower side which is the wiring substrate side when viewed from the power element-embedded substrate. In the case of a structure in which the power element-embedded substrates are mounted on both sides of the wiring substrate, a separate definition is required. Moreover, in an electronic device, “top (or upper or above)” is defined as an upper side which is the module unit side as viewed from the mounting substrate, and “bottom (or lower or below)” is defined as the lower side which is the mounting substrate side as viewed from the module unit side. In this specification, a top view may be rephrased as a plan view.

### First Embodiment

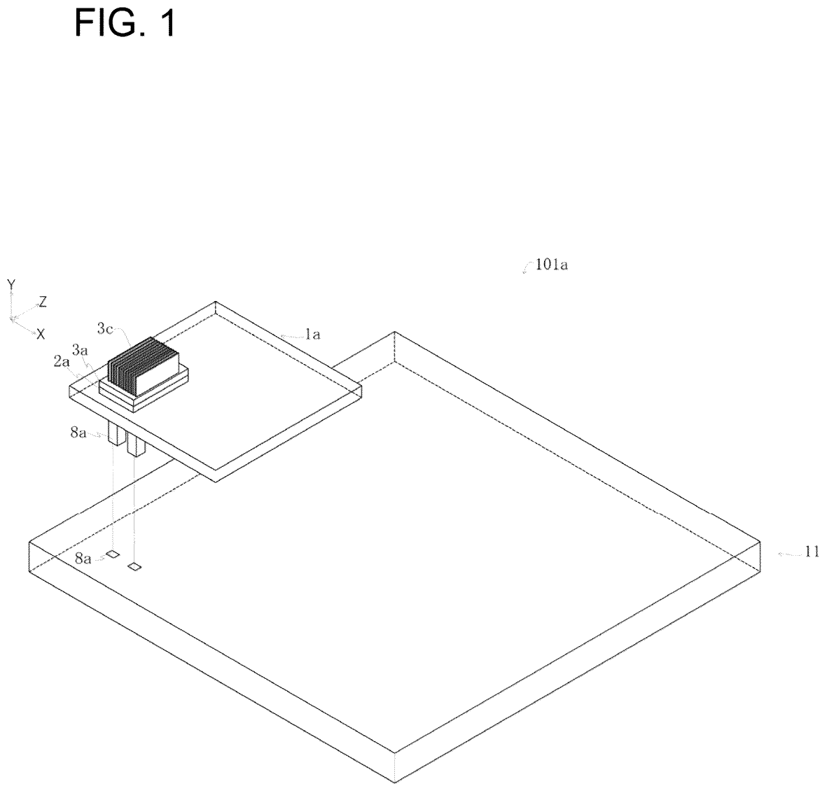

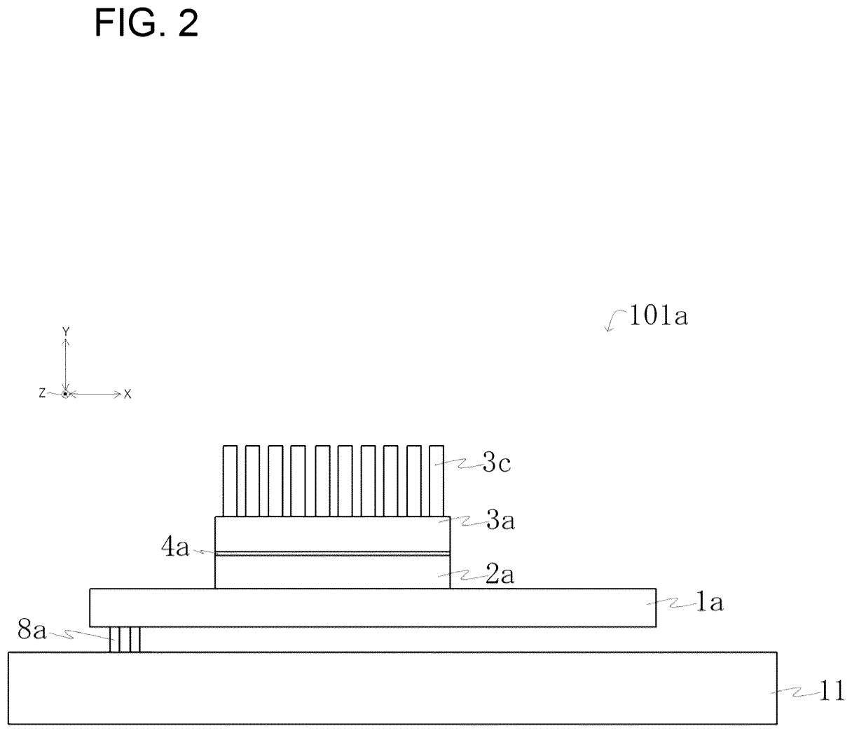

FIG. 1 is a schematical exploded perspective diagram illustrating an electronic device 101a according to a first embodiment. FIG. 2 is a schematic cross-sectional diagram illustrating the electronic device 101a, which is a cross section taken along a surface perpendicular to an Z direction and parallel to a stacking direction (Y direction) of a power element-embedded substrate 2a in FIG. 1. In the electronic device illustrated in FIGS. 1 and 2, a mounting substrate 11, a wiring substrate 1a, a power element-embedded substrate 2a, and a heat dissipation member 3a are stacked in this order. Moreover, a heat radiation fin 3c as a cooler is connected onto the heat dissipation member 3a. The heat radiation fin 3c may be bonded to the heat dissipation member 3a using a well-known conductive adhesion layer or the like. In the present disclosure, the cooler connected to the heat dissipation member 3a is not limited to the heat radiation fin 3c. For example, the heat dissipation member 3a may be connected to a housing. Although not illustrated in FIG. 1, an insulating member 4a may be disposed between the power element-embedded substrate 2a and the heat dissipation member 3a. In the electronic device disclosed herein, the insulating member 4a is not essential, and the heat dissipation member 3a and at least a portion of the power element-embedded substrate 2a may be in direct contact with each other.

Although not illustrated, for example, a gate driver, an input terminal, an output terminal, a control IC, and other passive components may be mounted on the mounting substrate. Moreover, in the present embodiment, one power element-embedded substrate is mounted on the wiring substrate 1a, but, in the present disclosure, the number of the power element-embedded substrates to be mounted is not limited to this example. In the present disclosure, one or more power element-embedded substrates may be further mounted on the wiring substrate 1a. In FIGS. 1 and/or 2, electrical connections for the wiring substrate, the power element-embedded substrate, and the mounting substrate are not illustrated, but each connection may be realized using a well-known method.

### (Wiring Substrate)

The first wiring substrate 1a and/or the second wiring substrate 1b (hereinafter, collectively referred to as “wiring substrate”) may be a dielectric substrate or may be a multilayered dielectric substrate. Moreover, the wiring substrate has a signal conductor pattern (not illustrated) wired on an upper surface and/or an inner layer. Although not illustrated, the wiring substrate 1a may have an electrode pattern or an electrode pin for connecting to a connector on the mounting substrate side for establishing electrical connection with the mounting substrate. Furthermore, a circuit component (e.g., passive component, such as a capacitor) other than the power element may be mounted on the wiring substrate 1a. Moreover, a gate driver may further be disposed on the wiring substrate 1a.

### (Power Element-Embedded Substrate)

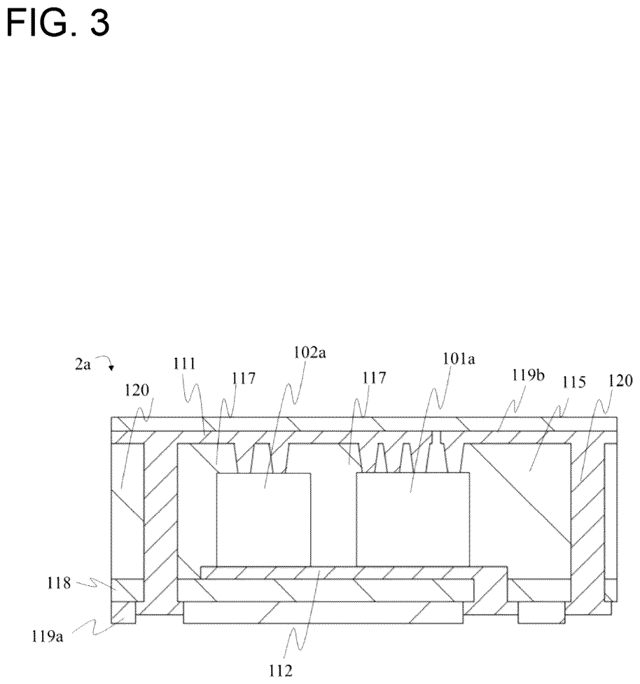

The power element-embedded substrate 2a is, for example, a multilayer wiring substrate in which a power element (diode, transistor, etc.) constituting a portion of the power conversion circuit is embedded. More specifically, for example, as illustrated in FIG. 3, the power element-embedded substrate 2a has a structure having an insulation layer 115 between a wiring layer (first wiring layer) 111 and a retention layer (second wiring layer) 112 so that a transistor 101a and a diode 102a as power elements are embedded in the insulation layer 115. In the power element-embedded substrate 2a illustrated in FIG. 3, the first wiring layer 111 constitutes an upper wiring layer, and the retention layer 112 constitutes a portion of the second wiring layer (lower wiring layer). The second wiring layer 112 is composed of a copper foil formed over both surfaces of a base material 118, and the copper foil on a first surface side of the base material 118 and a copper foil on a second surface side are electrically connected to each other through a through hole. Moreover, the diode 102a and the transistor 101a are placed respectively via adhesion layers (not illustrated) on the retention layer (copper foil on the first surface side) 112. The retention layer may constitute the second wiring layer, or may be composed of any other member (e.g., an insulating substrate, such as a metallic substrate or a ceramic substrate).

The diode 102a is, for example, a Schottky barrier diode (SBD), a fast recovery diode (FRD), or a PiN diode. Moreover, the transistor 101a is, for example, a metal oxide semiconductor field effect transistor (MOSFET) or an insulated gate bipolar transistor (IGBT). The semiconductor materials constituting the diode 102a and the transistor 101a as the power elements are not particularly limited. Examples of the semiconducting material include silicon, gallium nitride, silicon carbide, gallium oxide, and diamond. The power element-embedded substrate is manufactured using a known method of manufacturing a component-embedded substrate. A thickness of the power element-embedded substrate in the stacking direction (Y direction) is, for example, not more than 3 mm, or preferably not more than 1 mm. An area of the power element-embedded substrate as viewed from above is, for example, not more than 2000 mm², or preferably not more than 1000 mm².

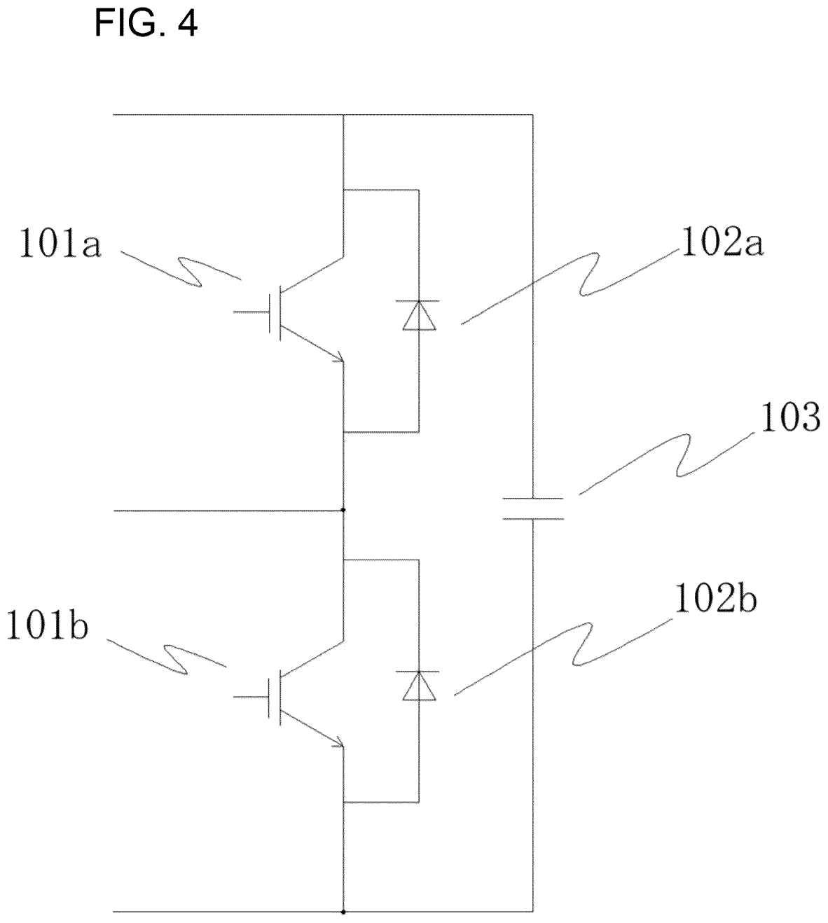

FIG. 4 is an equivalent circuit diagram for describing positioning in a circuit of a power element embedded in the power element-embedded substrate 2a. In a circuit configuration illustrated in FIG. 4, an anti-parallel circuit of a transistor 101a and a diode 102a and an anti-parallel circuit of a transistor 101b and a diode 102b are connected in series, and a capacitor 103 is further connected in parallel to the transistors 101a and 101b. The semiconductor circuit is applied to, for example, a power conversion circuit including an inverter circuit or a converter circuit.

In the present embodiment, the first power element-embedded substrate 2a is equipped with the transistor 101a and the diode 102a in the equivalent circuit illustrated in FIG. 4. Moreover, in the second embodiment, the second power element-embedded substrate 2b is equipped with the transistor 101b and the diode 102b in the equivalent circuit illustrated in FIG. 4. In the present disclosure, the power element-embedded substrate 2a may be equipped with a plurality of transistors (e.g., transistors 101a and 101b) and/or a plurality of diodes (e.g., diodes 102a and 102b). When the power element-embedded substrate is equipped with a plurality of transistors, the plurality of transistors may be electrically connected in series or in parallel to each other. In the present disclosure, the module unit may include a plurality of power element-embedded substrates as will be described later. It should be noted that the circuit configuration described above is merely an example, and other circuit configurations may be used. In the present disclosure, the power conversion circuit may be configured by combining a plurality of the power element-embedded substrates together with other passive components.

### (Heat Dissipation Member)

The heat dissipation member 3a is disposed in order to dissipate heat generated in the power element-embedded substrate. The material constituting the heat dissipation member is not particularly limited as long as it does not hinder the object of the present disclosure. Examples of the material constituting the heat dissipation member include metal materials, ceramic materials, carbon-based materials, and composite materials thereof. In the present disclosure, the heat dissipation member is preferably a metal block. In the present disclosure, a surface side facing the power element-embedded substrate may have a recessed portion. The metal block has, for example, a rectangular shape or circular shape in a plan view. Moreover, the metal block has a larger shape than the power element-embedded substrate in a plan view. The recessed portion is formed using a well-known metal processing method (punching, laser machining, cut machining, metal plating, 3D printer, etc.). Moreover, the material constituting the metal block is not particularly limited as long as it does not hinder the object of the present disclosure. Examples of the material constituting the metal block include Cu, Au, Al, Ag, Fe, Ti, Ni, Pt, Pd, and alloys thereof (which may contain other metals or carbon, etc.). In the present disclosure, the material constituting the metal block preferably contains copper (Cu) or aluminum (Al), and more preferably contains aluminum (Al). In the present disclosure, it is preferable that the periphery of the power element-embedded substrate is covered with the recessed portion of the metal block. Moreover, a depth of the recessed portion is not particularly limited. The depth of the recessed portion is, for example, not more than 5 mm, preferably not more than 3 mm, and more preferably not more than 1 mm.

In the present disclosure, for example, as illustrated in FIG. 2, the insulating member 4a may be disposed between the heat dissipation member 3a and the power element-embedded substrate 2a. The insulating member 4a preferably has high thermal conductivity, and more specifically, is made of a well-known Thermal Interface Material (TIM), such as a layer of a resin such as an epoxy resin containing a filler such as boron nitride (BN), aluminum nitride (AlN), or alumina (Al₂O₃).

### Example of Manufacturing Method

Hereinafter, a method of manufacturing the electronic device having the above-described structure will be described.

In an assembly process of the module unit, the power element-embedded substrate 2a is connected to (mounted on) the wiring substrate 1a by using a well-known method. Thereafter, the heat dissipation member 3a is bonded onto the power element-embedded substrate 2a, via the insulating member 4a having excellent thermal conductivity as desired. The bonding may be performed, for example, using a conductive adhesion layer (not illustrated), or may be performed by fixing components by screwing through a through-hole formed in each component. The through-hole may be formed before the above-described stacking process or may be formed after the stacking process. In the present embodiment, the method of fixing the wiring substrate 1a, the power element-embedded substrate 2a, and the heat dissipation member 3a is not limited to this example. For example, a method of fixing using a busbar or a method of fixing using a clip may be used. Moreover, the module unit constituted of the wiring substrate 1a, the power element-embedded substrate 2a, the heat dissipation member 3a, and the cooling fin 3c is mounted on the mounting substrate 11 using a well-known method. In the present embodiment, a connector 8a is attached to the wiring substrate 1a using a well-known method, and a connector insertion portion 8b is formed on the mounting substrate side. Then, by inserting the connector 8a into the connector insertion portion 8b, it is possible to mount the module unit on the mounting substrate so that the wiring substrate is parallel to or approximately parallel to the mounting substrate. The manufacturing method of the electronic device described above is merely an example, and other methods may be used. For example, the assembly process of the module unit is not limited to the steps described above, and steps may be added or deleted, or the order of steps may be changed, etc., without departing from the spirit and technical concept.

### Advantageous Effects of First Embodiment

As described above, in the electronic device 101a of the present embodiment, the power element-embedded substrate is disposed on the wiring substrate 1a, and the module unit in which the heat dissipation member 3a is connected to the power element-embedded substrate 2a side is mounted so as to be parallel to or approximately parallel to the mounting substrate. Therefore, it is possible to provide the configuration that is excellent in dissipating heat from the power element-embedded substrate while making it easier to design the mounting substrate side. Moreover, the present embodiment has excellent handleability since the wiring substrate, the power element-embedded substrate, and the metal block are integrated together. Furthermore, by combining a plurality of module units, it is possible to improve flexibility of implementation design of the entire power conversion circuit, for example, even without having to perform strict design of heat dissipation and noise characteristics.

### Second Embodiment

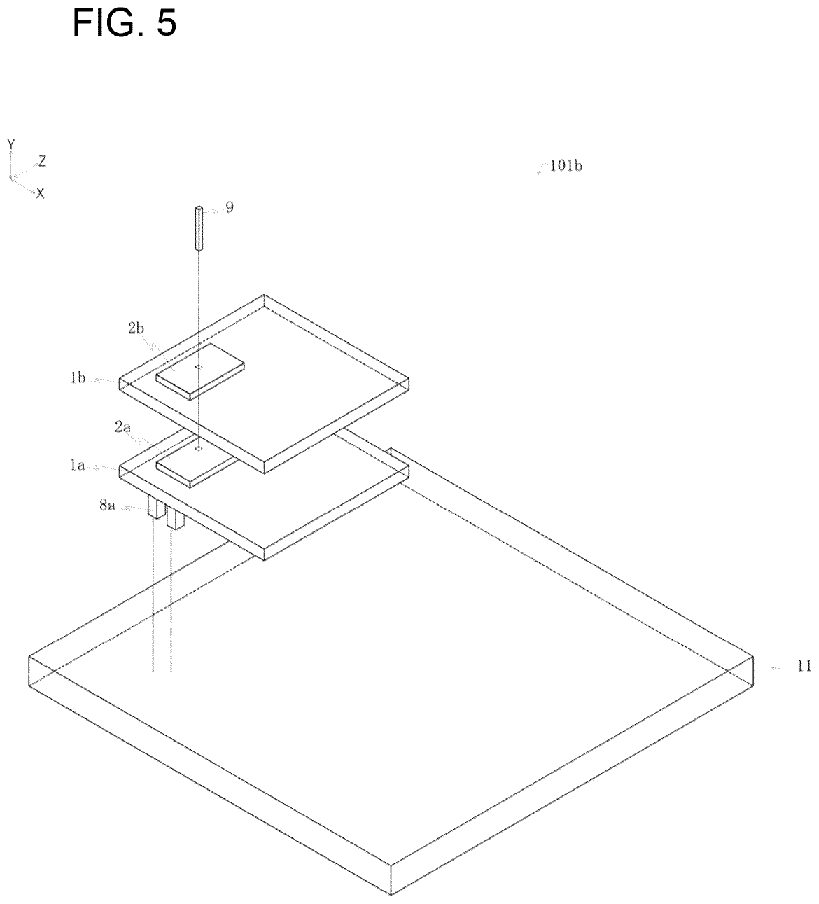

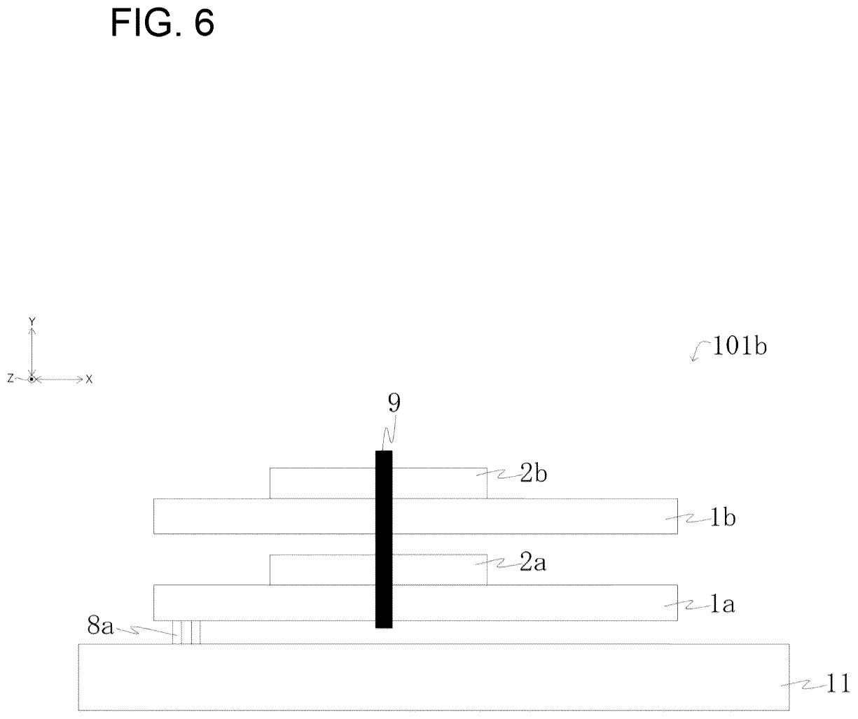

FIG. 5 is a schematic exploded perspective diagram illustrating an electronic device 101b according to a second embodiment, and FIG. 6 illustrates a schematic cross section thereof. In the electronic device 101b illustrated in FIG. 5, a power element-embedded substrate 2a is mounted on a first wiring substrate 1a to constitute a first module unit, and a second module unit having a second wiring substrate 1b and a second power element-embedded substrate 2b disposed on the second wiring substrate 1b, is stacked on the first module unit. Moreover, a through-hole is formed in the first module unit and the second module unit, and the respective components are fixed to one another with a screw 9.

### Advantageous Effects of Second Embodiment

According to the electronic device illustrated in FIGS. 5 and 6, the second module unit is further formed on the first module unit. Therefore, even if one power element-embedded substrate is damaged, it is possible to realize a paralleling function of partially disconnecting the damaged substrate from the circuit and maintaining the performance by the other module unit. Moreover, by stacking the wiring substrates, the number of power element-embedded substrates is increased, and thereby it is possible to realize multi-functionality while reducing an effect of warping due to inductance and the thermal expansion coefficient.

### Third Embodiment

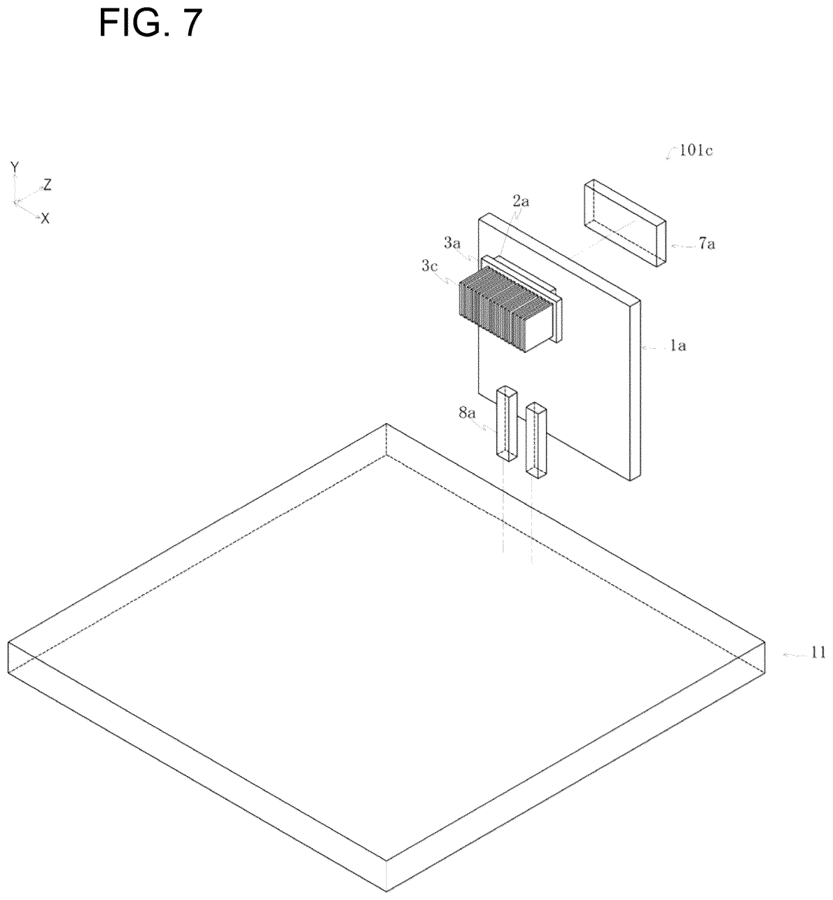

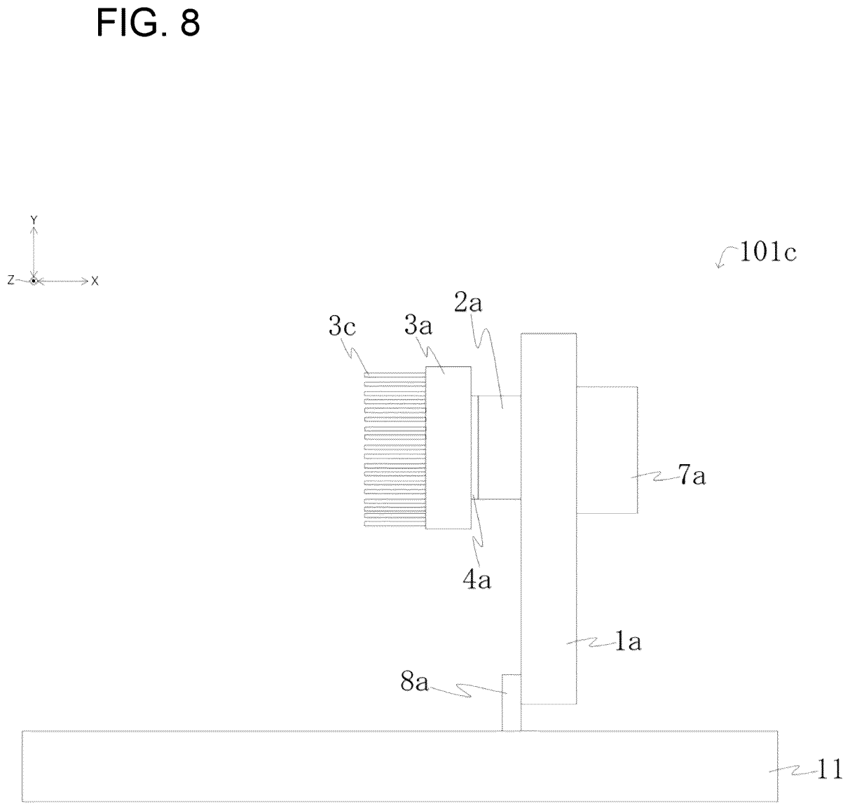

FIG. 7 is a schematic exploded perspective diagram illustrating an electronic device 101c according to a third embodiment, and FIG. 8 illustrates a schematic cross-sectional diagram thereof. . . . In the electronic device 101c illustrated in FIG. 7, a power element-embedded substrate 2a, a heat dissipation member 3a, and a heat radiation fin (cooler) 3c are stacked in this order on a first surface of a first wiring substrate 1a. The connections of each component are made using the methods described above. Moreover, in the present embodiment, a gate driver 7a of the power element equipped in the power element-embedded substrate is disposed on a second surface side opposite to the first surface of the wiring substrate 1a. The gate driver 7a is composed of an IC equipped with a drive circuit of controlling the switching operation of a gate electrode of the power element disposed in the power element-embedded substrate. In the present embodiment, the wiring substrate 1a includes a connector 8a on the first surface side, and a module unit (wiring substrate) is longitudinally provided on a mounting substrate 11 by inserting the connector 8a into a connector insertion portion (not illustrated) formed on the mounting substrate.

### Advantageous Effects of Third Embodiment

According to the third embodiment, since the gate driver is disposed on a surface (second surface) side opposite to the power element-embedded substrate, it is possible to realize a configuration in which noise is further suppressed. Furthermore, since the heat dissipation unit 3a and the heat radiation fin (cooler) are disposed on the power element-embedded substrate side, it is possible to further satisfactorily dissipate heat generated in the power element-embedded substrate. Furthermore, since the wiring substrate 1a is longitudinally provided on the mounting substrate 11, it is also possible to realize space saving on the mounting substrate 11.

### Fourth Embodiment

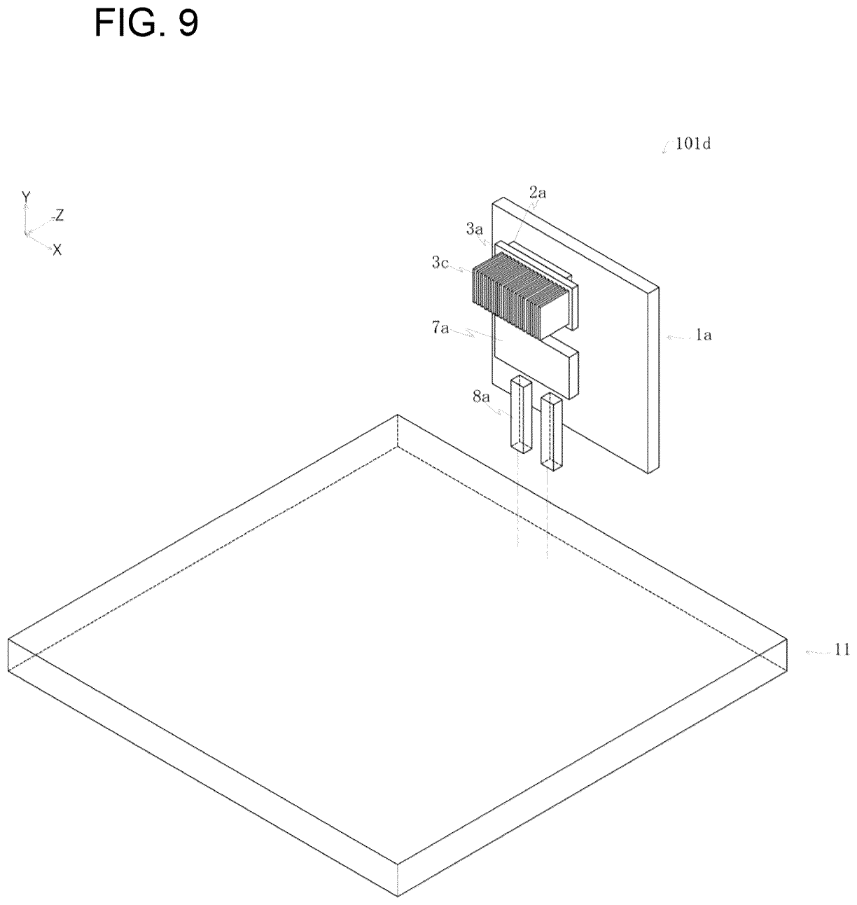

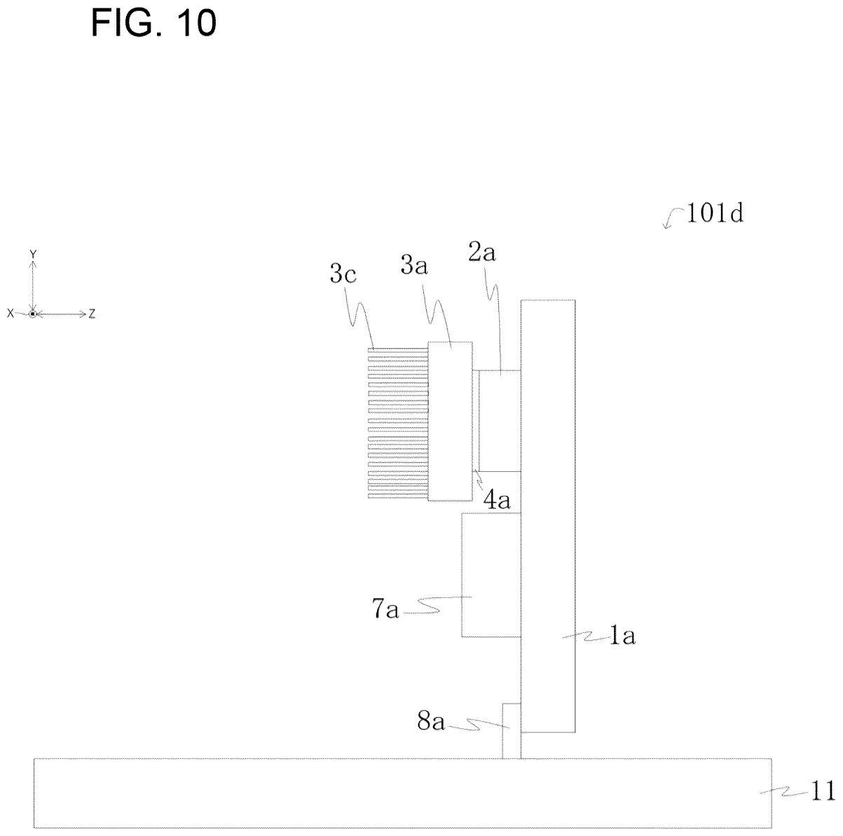

FIG. 9 is a schematic exploded perspective diagram illustrating an electronic device 101d according to a fourth embodiment, and FIG. 10 illustrates a schematic cross-sectional diagram thereof. The electronic device 101d illustrated in FIGS. 9 and 10 is different from the electronic device 101c illustrated in FIGS. 7 and 8 in that the gate driver 7a is disposed on the first surface side of the wiring substrate 1a.

### Advantageous Effects of Fourth Embodiment

According to the electronic device 101d illustrated in FIGS. 9 and 10, since the power element-embedded substrate 2a and the gate driver 7a are disposed on the first surface side of the wiring substrate and the heat dissipation member 3a and the heat radiation fin (cooler) 3c are disposed on the power element-embedded substrate, it is possible to reduce noise while also reducing the effect of heat generated in the power element-embedded substrate on the gate driver. Moreover, in the present embodiment, as illustrated in FIGS. 9 and 10, it is preferable that the gate driver 7a is disposed at a position closer to the mounting substrate 11 than the power element-embedded substrate 2a. In accordance with such a configuration, it is possible to prevent the heat generated in the power element-embedded substrate from affecting other electronic components on the mounting substrate 11.

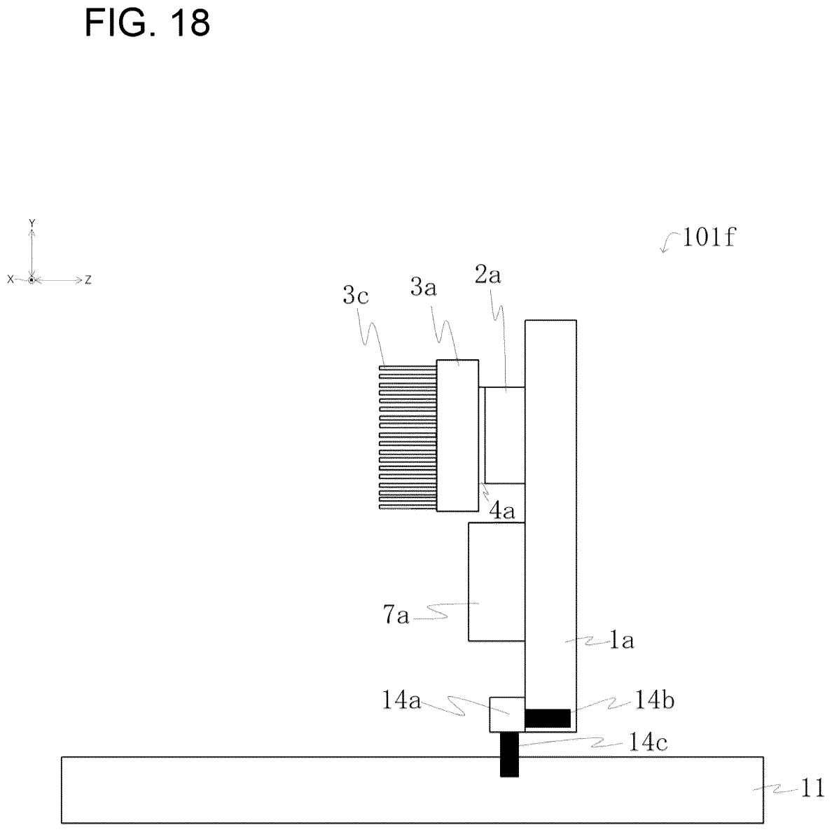

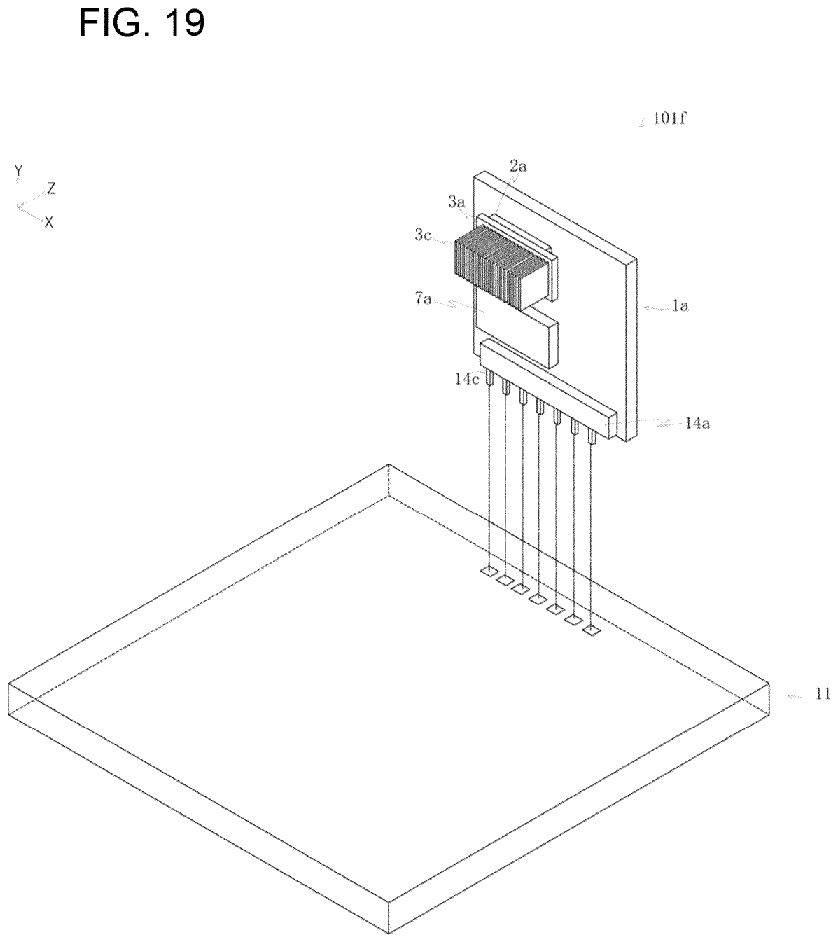

FIGS. 18 and 19 illustrate another aspect of the electronic device of the present disclosure, as a modified example 1. FIG. 18 illustrates a cross-sectional diagram schematically illustrating a state where a wiring substrate 1a is longitudinally provided on a mounting substrate 11, and FIG. 19 illustrates an exploded perspective diagram thereof. As illustrated in FIGS. 18 and 19, the wiring substrate 1a is connected to the mounting substrate 11 using a connection member including a resin portion 14a and pin portions 14b and 14c. As illustrated in FIG. 18, the pin portion 14b extending in the Z direction so as to be connected to the wiring substrate 1a, and the pin portion 14c extending in the Y direction so as to be connected to the mounting substrate 11 are connected by being inserted into the resin portion 14a.

### Fifth Embodiment

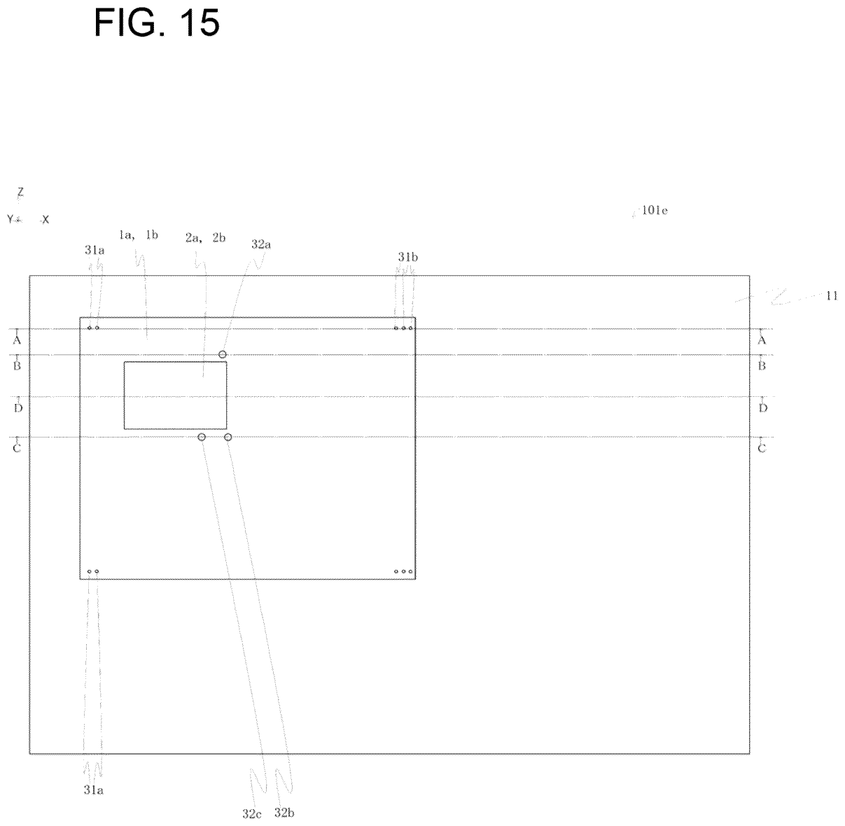

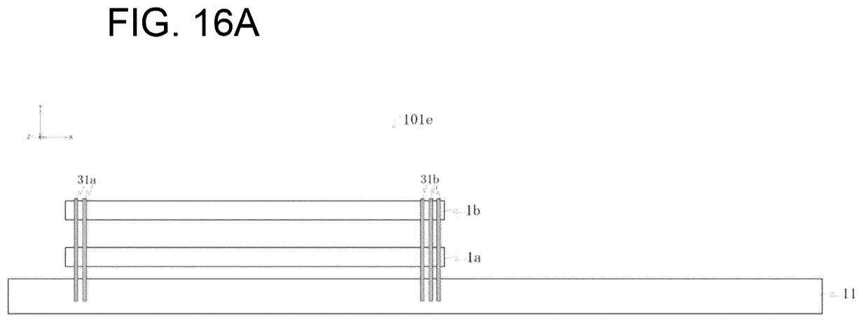

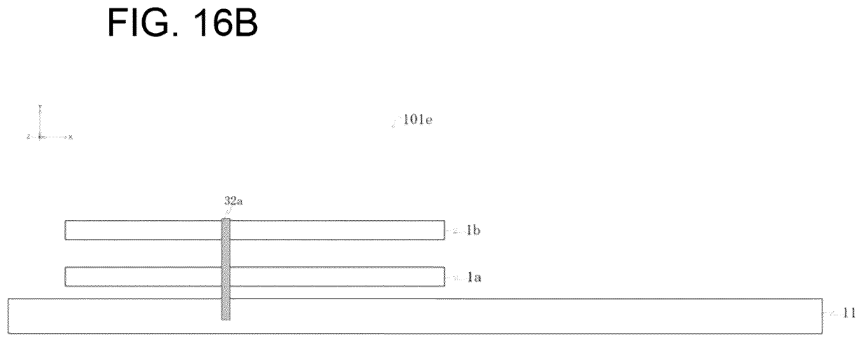

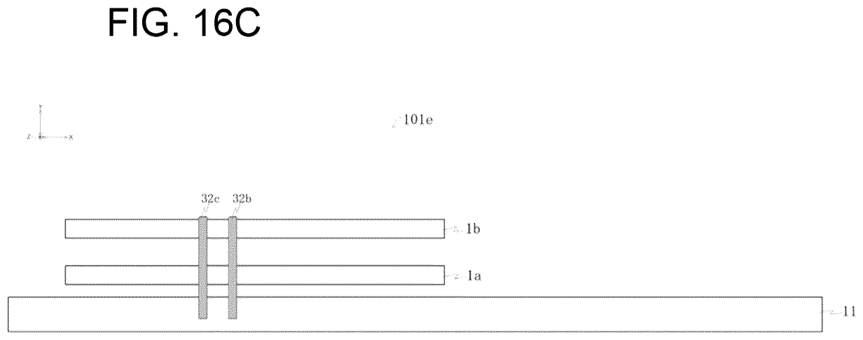

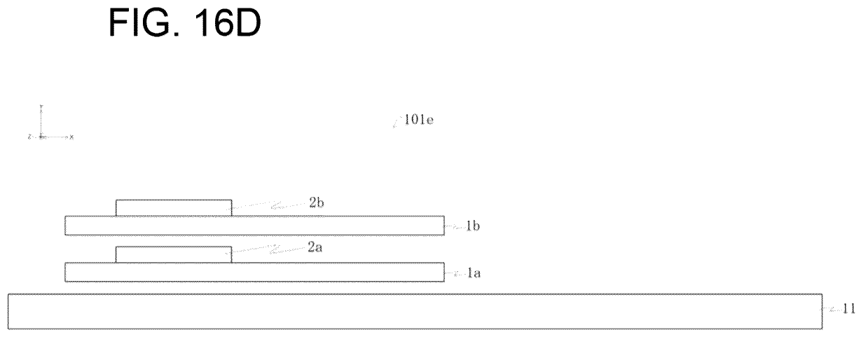

One aspect of a method of fixing and electrical connection between components in an electronic device will now be described with reference to FIGS. 15 to 17, as a fifth embodiment. FIGS. 15 and 16 are a top view diagram and a cross-sectional diagram schematically illustrating an electronic device 101e according to the present embodiment. FIGS. 16A, 16B, 16C, and 16D illustrate respectively cross sections taken along lines A-A, B-B, C-C, and D-D of FIG. 15. As illustrated in FIGS. 15 and 16, an input pin 32a, an output pin 32b, and a GND pin 32c for connecting a power element-embedded substrate of the module unit to a power source, another component, a wiring substrate, and/or a mounting substrate, and power supply pins 31a and signal pins 31b for connecting the other component on the wiring substrate or the wiring substrate to other components, etc. are arranged to pass through the wiring substrate 1a. In the present disclosure, the input pin 32a, the output pin 32b and the GND pin 32c are electrically connected to corresponding electrode pads (signal pads, power supply pads, etc.) on the power element-embedded substrate 2a using wiring patterns or the like, which are not illustrated. In the present disclosure, the input pin 32a, the output pin 32b and the GND pin 32c are preferably located outside and near the outer periphery of the power element-embedded substrate in a plan view (top view).

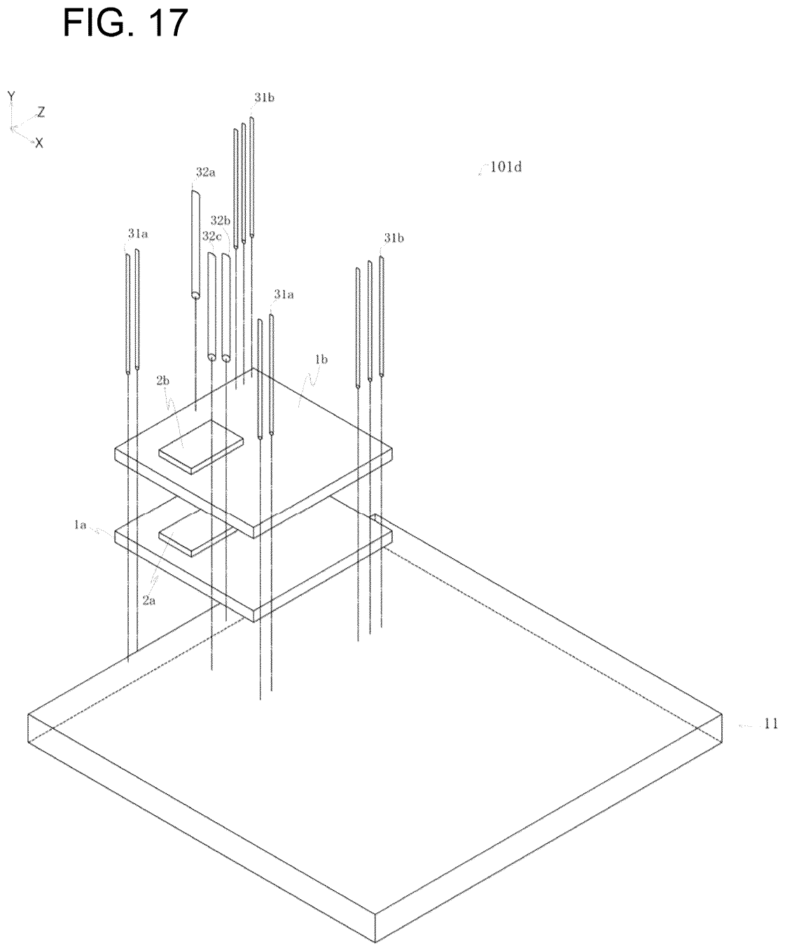

FIG. 17 is an exploded perspective diagram schematically illustrating the electronic device 101e illustrated in FIGS. 15 and 16. As illustrated in FIG. 17, the electronic device 101e may be mounted so that each electrode pin (the input pin 32a, the output pin 32b, the GND pin 32c, the signal pins 31b, the power supply pins 31a) is inserted into the mounting substrate. In this case, a hole (not illustrated) corresponding to each pin is formed on the mounting substrate 11. The method of mounting on the mounting substrate of the module unit in the electronic device 101e is not limited to the above-described configuration.

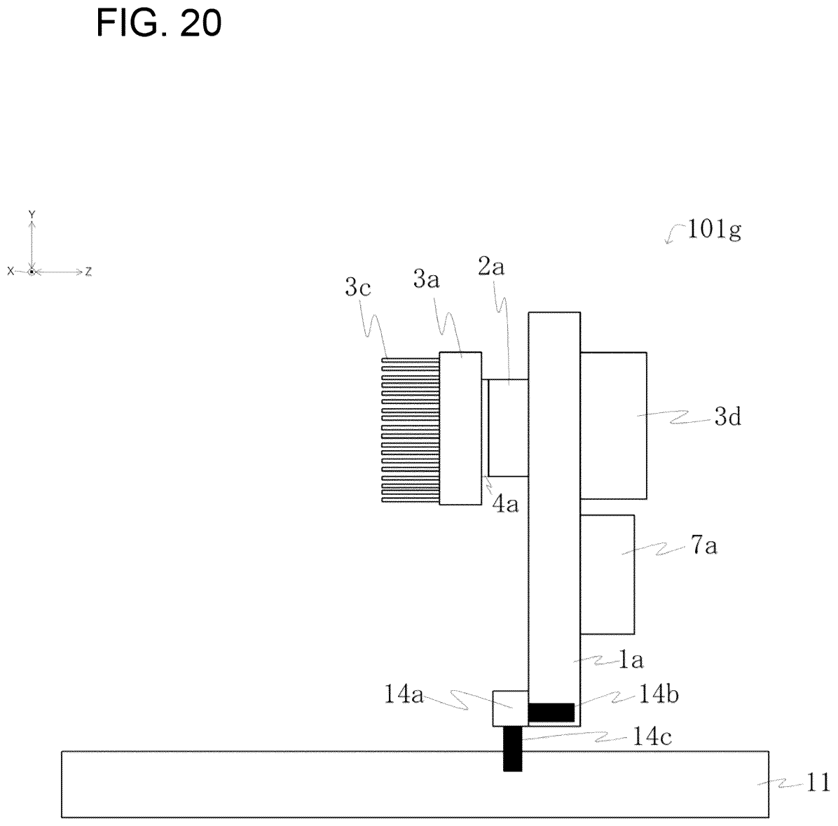

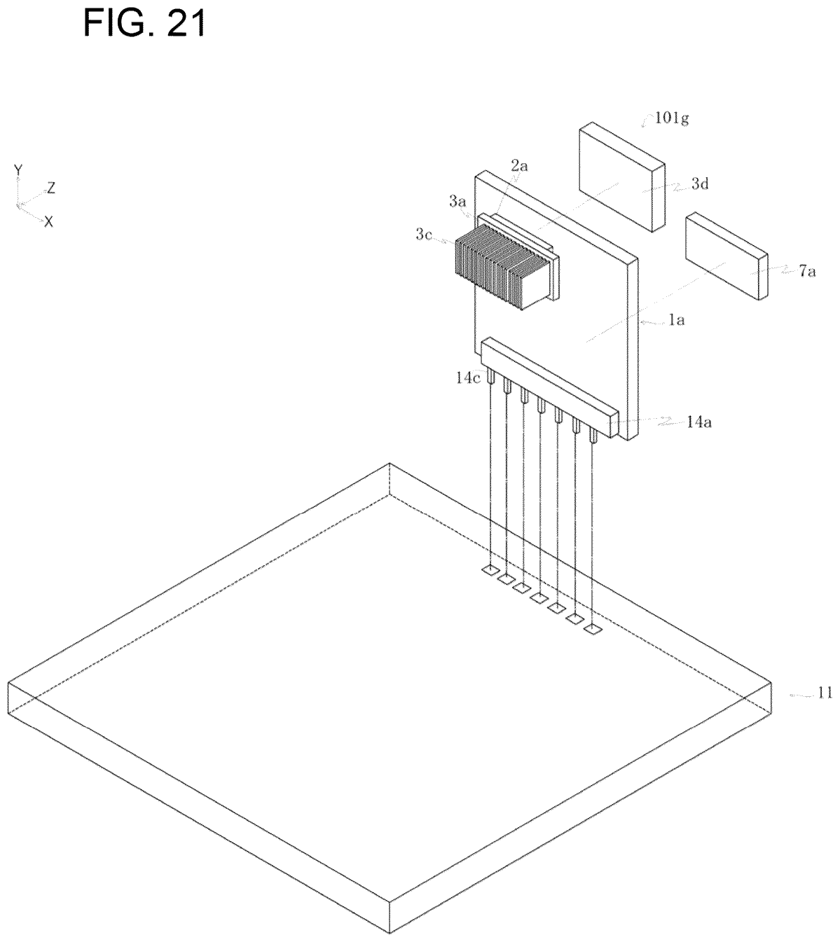

FIGS. 20 and 21 are a cross-sectional diagram and an exploded perspective diagram schematically illustrating an electronic device 101g according to a modified example 2. In the electronic device 101g in FIGS. 20 and 21, a heat dissipation member 3b and a gate driver 7a for controlling a power element in a power element-embedded substrate 2a are arranged on a surface side of the wiring substrate opposite to the power element-embedded substrate 2a. According to the electronic device 101g illustrated in FIGS. 20 and 21, since the heat dissipation members (metal blocks) are arranged on both surfaces of the module unit, it is possible to realize a configuration having excellent heat dissipation. Moreover, since the heat dissipation member is disposed also on a back surface side, it is possible to further downsize each heat dissipation member (metal block). Furthermore, according to the electronic device 101g in FIGS. 20 and 21, since the gate driver 7a is disposed on the back surface side of the module unit, it is possible to further reduce inductance while minimizing the area of the substrate. Moreover, in the present disclosure, as in a electronic device 101g in FIG. 20, the power element-embedded substrate 2a and the gate driver 7a may be disposed at positions not overlapping one another in a plan view (when viewed in the Z direction). By arranging in this manner, it is possible to further satisfactorily reduce an influence of heat generated from the power element-embedded substrate 2a on the gate driver 7a. Alternatively, in the present disclosure, the power element-embedded substrate 2a and the gate driver 7a may partly overlap one another in a plan view (when viewed in the Z direction). When an overlapping rate in a plan view is small (e.g., not more than 50% of an area of the power element-embedded substrate, and preferably not more than 30% in a plan view), it is possible to reduce the influence of heat.

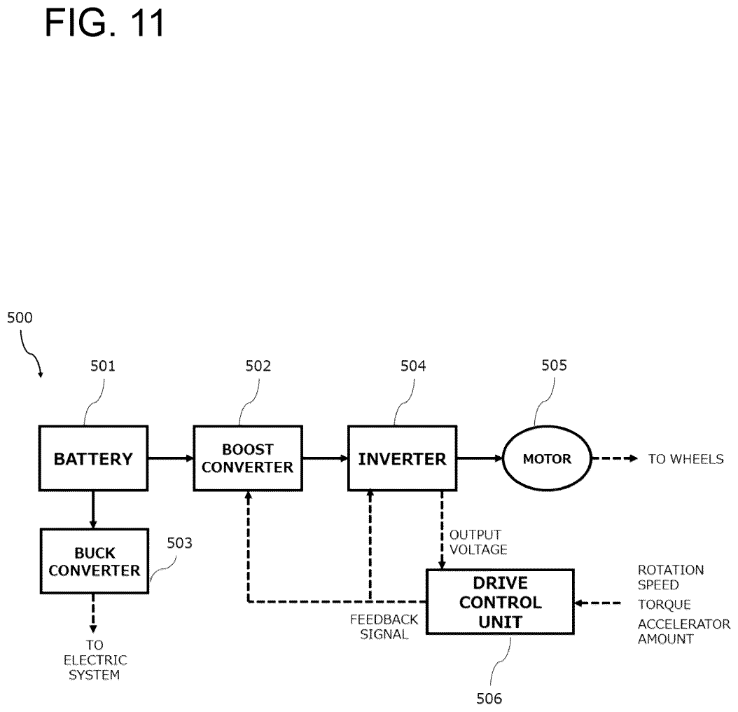

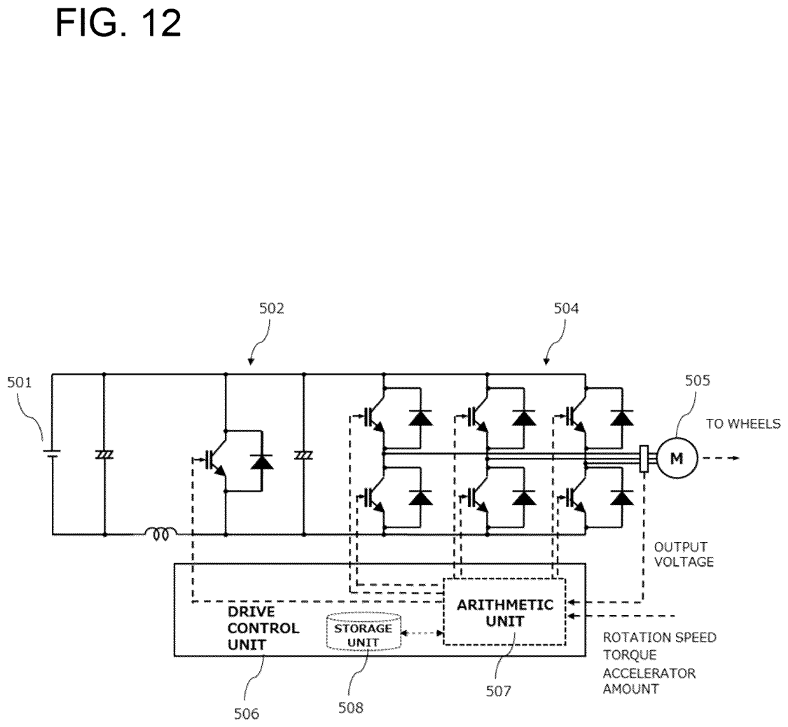

In order to exhibit the functions described above, the electronic device of the disclosure described above may be applied to a power converter such as an inverter or a converter. FIG. 11 is a block diagram illustrating an exemplary control system applying an electronic device according to an embodiment of the disclosure, and FIG. 12 is a circuit diagram of the control system particularly suitable for applying to a control system of an electric vehicle.

As shown in FIG. 11, the control system 500 includes a battery (power supply) 501, a boost converter 502, a buck converter 503, an inverter 504, a motor (driving object) 505, a drive control unit 506, which are mounted on an electric vehicle. The battery 501 consists of, for example, a storage battery such as a nickel hydrogen battery or a lithium-ion battery. The battery 501 may store electric power by charging at the power supply station or regenerating at the time of deceleration, and to output a direct current (DC) voltage required for the operation of the driving system and the electrical system of the electric vehicle. The boost converter 502 is, for example, a voltage converter in which a chopper circuit is mounted, and may step-up DC voltage of, for example, 200V supplied from the battery 501 to, for example, 650V by switching operations of the chopper circuit. The step-up voltage may be supplied to a traveling system such as a motor. The buck converter 503 is also a voltage converter in which a chopper circuit is mounted, and may step-down DC voltage of, for example, 200V supplied from the battery 501 to, for example, about 12V. The step-down voltage may be supplied to an electric system including a power window, a power steering, or an electric device mounted on a vehicle.

The inverter 504 converts the DC voltage supplied from the boost converter 502 into three-phase alternating current (AC) voltage by switching operations, and outputs to the motor 505. The motor 505 is a three-phase AC motor constituting the traveling system of an electric vehicle, and is driven by an AC voltage of the three-phase output from the inverter 504. The rotational driving force is transmitted to the wheels of the electric vehicle via a transmission mechanism (not shown).

On the other hand, actual values such as rotation speed and torque of the wheels, the amount of depression of the accelerator pedal (accelerator amount) are measured from an electric vehicle in cruising by using various sensors (not shown), The signals thus measured are input to the drive control unit 506. The output voltage value of the inverter 504 is also input to the drive control unit 506 at the same time. The drive control unit 506 has a function of a controller including an arithmetic unit such as a CPU (Central Processing Unit) and a data storage unit such as a memory, and generates a control signal using the inputted measurement signal and outputs the control signal as a feedback signal to the inverters 504, thereby controlling the switching operation by the switching elements. The AC voltage supplied to the motor 505 from the inverter 504 is thus corrected instantaneously, and the driving control of the electric vehicle may be executed accurately. Safety and comfortable operation of the electric vehicle is thereby realized. In addition, it is also possible to control the output voltage to the inverter 504 by providing a feedback signal from the drive control unit 506 to the boost converter 502.

FIG. 12 is a circuit configuration excluding the buck converter 503 in FIG. 11, in other words, a circuit configuration showing a configuration only for driving the motor 505. As shown in the FIG. 12, the electronic device of the disclosure is provided for switching control by, for example, being applied to the boost controller 502 and the inverter 504 as a Schottky barrier diode. The boost converter 502 performs chopper control by incorporating the semiconductor device into the chopper circuit of the boost converter 502. Similarly, the inverter 504 performs switching control by incorporating the semiconductor device into the switching circuit including an IGBT of the inverter 504. The current may be stabilized by interposing an inductor (such as a coil) at the output of the battery 501. Also, the voltage may be stabilized by interposing a capacitor (such as an electrolytic capacitor) between each of the battery 501, the boost converter 502, and the inverter 504.

As indicated by a dotted line in FIG. 12, an arithmetic unit 507 including a CPU (Central Processing Unit) and a storage unit 508 including a nonvolatile memory are provided in the drive control unit 506. Signal input to the drive control unit 506 is given to the arithmetic unit 507, and a feedback signal for each semiconductor element is generated by performing the programmed operation as necessary. The storage unit 508 temporarily holds the calculation result by the calculation unit 507, stores physical constants and functions necessary for driving control in the form of a table, and outputs the physical constants, functions, and the like to the arithmetic unit 507 as appropriate. The arithmetic unit 507 and the storage unit 508 may be provided by a known configuration, and the processing capability and the like thereof may be arbitrarily selected.

As shown in FIGS. 11 and 12, a diode and a switching element such as a thyristor, a power transistor, an IGBT, a MOSFET and the like is employed for the switching operation of the boost converter 502, the buck converter 503 and the inverter 504 in the control system 500. The use of gallium oxide (Ga2O3) specifically corundum-type gallium oxide (α-Ga2O3) as its materials for these semiconductor devices greatly improves switching properties. Further, extremely outstanding switching performance may be expected and miniaturization and cost reduction of the control system 500 may be realized by applying an electronic device of the disclosure. That is, each of the boost converter 502, the buck converter 503 and the inverter 504 may be expected to have the benefit of the disclosure, and the effect and the advantages may be expected in any one or combination of the boost converter 502, the buck converter 503 and the inverter 504, or in any one of the boost converter 502, the buck converter 503 and the inverter 504 together with the drive control unit 506.

The control system 500 described above is not only applicable to the control system of an electric vehicle of the electronic device of the disclosure, but may be applied to a control system for any applications such as to step-up and step-down the power from a DC power source, or convert the power from a DC to an AC. It is also possible to use a power source such as a solar cell as a battery.

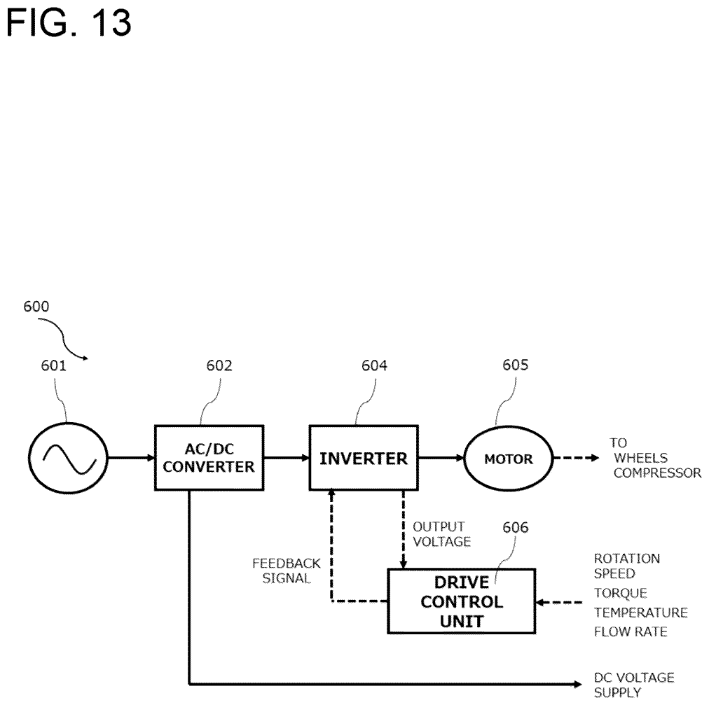

FIG. 13 is a block diagram illustrating another exemplary control system applying an electronic device according to an embodiment of the disclosure, and FIG. 13 is a circuit diagram of the control system suitable for applying to infrastructure equipment and home appliances or the like operable by the power from the AC power source.

As shown in FIG. 13, the control system 600 is provided for inputting power supplied from an external, such as a three-phase AC power source (power supply) 601, and includes an AC/DC converter 602, an inverter 604, a motor (driving object) 605 and a drive control unit 606 that may be applied to various devices described later. The three-phase AC power supply 601 is, for example, a power plant (such as a thermal, hydraulic, geothermal, or nuclear plant) of an electric power company, whose output is supplied as an AC voltage while being downgraded through substations. Further, the three-phase AC power supply 601 is installed in a building or a neighboring facility in the form of a private power generator or the like for supplying the generated power via a power cable. The AC/DC converter 602 is a voltage converter for converting AC voltage to DC voltage. The AC/DC converter 602 converts AC voltage of 100V or 200V supplied from the three-phase AC power supply 601 to a predetermined DC voltage. Specifically, AC voltage is converted by a transformer to a desired, commonly used voltage such as 3. 3V, 5V, or 12V. When the driving object is a motor, conversion to 12V is performed. It is possible to adopt a single-phase AC power supply in place of the three-phase AC power supply. In this case, same system configuration may be realized if an AC/DC converter of the single-phase input is employed.

The inverter 604 converts the DC voltage supplied from the AC/DC converter 602 into three-phase AC voltage by switching operations and outputs to the motor 605. Configuration of the motor 605 is variable depending on the control object. It may be a wheel if the control object is a train, may be a pump and various power source if the control objects a factory equipment, may be a three-phase AC motor for driving a compressor or the like if the control object is a home appliance. The motor 605 is driven to rotate by the three-phase AC voltage output from the inverter 604, and transmits the rotational driving force to the driving object (not shown).

There are many kinds of driving objects such as personal computer, LED lighting equipment, video equipment, audio equipment and the like capable of directly supplying a DC voltage output from the AC/DC converter 602. In that case the inverter 604 becomes unnecessary in the control system 600, and a DC voltage from the AC/DC converter 602 is supplied to the driving object directly as shown in FIG. 13. Here, DC voltage of 3. 3V is supplied to personal computers and DC voltage of 5V is supplied to the LED lighting device for example.

On the other hand, rotation speed and torque of the driving object, measured values such as the temperature and flow rate of the peripheral environment of the driving object, for example, is measured using various sensors (not shown), these measured signals are input to the drive control unit 606. At the same time, the output voltage value of the inverter 604 is also input to the drive control unit 606. Based on these measured signals, the drive control unit 606 provides a feedback signal to the inverter 604 thereby controls switching operations by the switching element of the inverter 604. The AC voltage supplied to the motor 605 from the inverter 604 is thus corrected instantaneously, and the operation control of the driving object may be executed accurately. Stable operation of the driving object is thereby realized. In addition, when the driving object may be driven by a DC voltage, as described above, feedback control of the AC/DC converter 602 is possible in place of feedback control of the inverter 604.

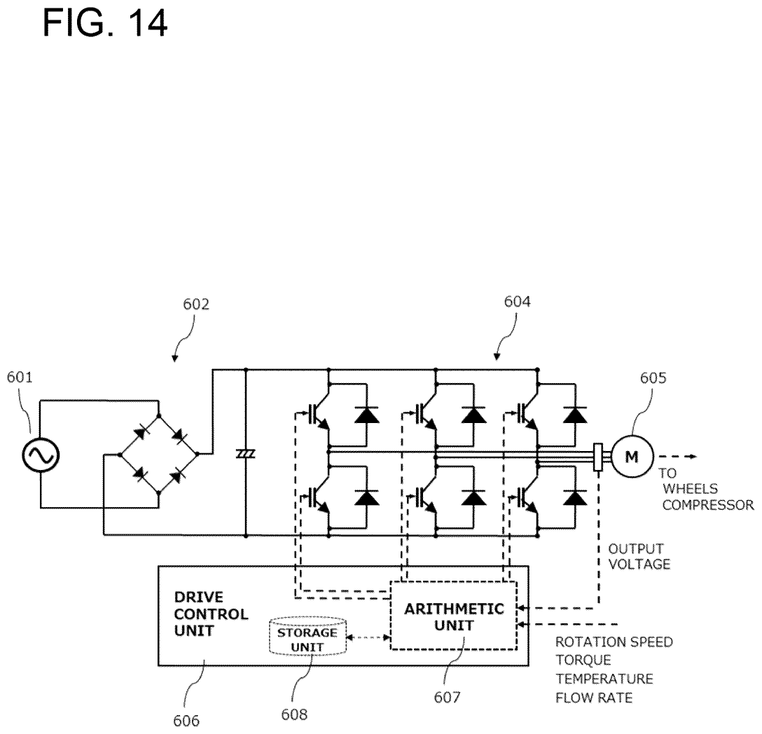

FIG. 14 shows the circuit configuration of FIG. 13. As shown in FIG. 14, the electronic device of the disclosure is provided for switching control by, for example, being applied to the AC/DC converter 602 and the inverter 604 as a Schottky barrier diode. The AC/DC converter 602 has, for example, a circuit configuration in which Schottky barrier diodes are arranged in a bridge-shaped, to perform a direct-current conversion by converting and rectifying the negative component of the input voltage to a positive voltage. Schottky barrier diodes may also be applied to a switching circuit in IGBT of the inverter 604 to perform switching control. The voltage may be stabilized by interposing a capacitor (such as an electrolytic capacitor) between the AC/DC converter 602 and the inverter 604.

As indicated by a dotted line in FIG. 14, an arithmetic unit 607 including a CPU and a storage unit 608 including a nonvolatile memory are provided in the drive control unit 606. Signal input to the drive control unit 606 is given to the arithmetic unit 607, and a feedback signal for each semiconductor element is generated by performing the programmed operation as necessary. The storage unit 608 temporarily holds the calculation result by the arithmetic unit 607, stores physical constants and functions necessary for driving control in the form of a table, and outputs the physical constants, functions, and the like to the arithmetic unit 607 as appropriate. The arithmetic unit 607 and the storage unit 608 may be provided by a known configuration, and the processing capability and the like thereof may be arbitrarily selected.

In such a control system 600, similarly to the control system 500 shown in FIGS. 11 and 12, a diode or a switching element such as a thyristor, a power transistor, an IGBT, a MOSFET or the like is also applied for the purpose of the rectification operation and switching operation of the AC/DC converter 602 and the inverter 604. Switching performance may be improved by the use of gallium oxide (Ga2O3), particularly corundum-type gallium oxide (α-Ga2O3), as materials for these semiconductor elements. Further, extremely outstanding switching performance may be expected and miniaturization and cost reduction of the control system 600 may be realized by applying an electronic device of the disclosure. That is, each of the AC/DC converter 602 and the inverter 604 may be expected to have the benefit of the disclosure, and the effects and the advantages of the disclosure may be expected in any one or combination of the AC/DC converter 602 and the inverter 604, or in any of the AC/DC converter 602 and the inverter 604 together with the drive control unit 606.

Although the motor 605 has been exemplified in FIGS. 13 and 14, the driving object is not necessarily limited to those that operate mechanically. Many devices that require an AC voltage may be a driving object. It is possible to apply the control system 600 as long as electric power is obtained from AC power source to drive the driving object. The control system 600 may be applied to the driving control of any electric equipment such as infrastructure equipment (electric power facilities such as buildings and factories, telecommunication facilities, traffic control facilities, water and sewage treatment facilities, system equipment, labor-saving equipment, trains and the like) and home appliances (refrigerators, washing machines, personal computers, LED lighting equipment, video equipment, audio equipment and the like).

### [Additional Note]

As described above, the present embodiments include the following disclosure.

### [Structure 1]

An electronic device including:
a module unit including a wiring substrate and a power element-embedded substrate mounted on the wiring substrate; and a mounting substrate,
the module unit being mounted on the mounting substrate so that the wiring substrate is parallel to or substantially parallel to the mounting substrate, a heat dissipation member for thermally dissipating heat from the power element-embedded substrate being disposed on the power element-embedded substrate side of the wiring substrate.

### [Structure 2]

An electronic device including:
a first module unit including a first wiring substrate and a first power element-embedded substrate mounted on the first wiring substrate;
a second module unit including a second wiring substrate and a second power element-embedded substrate mounted on the second wiring substrate; and a mounting substrate,
the first module unit being mounted so that the first wiring substrate is parallel to or substantially parallel to the mounting substrate, the second module unit being stacked on the first module unit.

### [Structure 3]

An electronic device including:
a module unit including a wiring substrate, and a power element-embedded substrate and a gate driver mounted on the wiring substrate; and a mounting substrate,
the module unit being longitudinally provided on the mounting substrate, the power element-embedded substrate and the gate driver being disposed on a first surface side of the wiring substrate, a heat dissipation member for thermally dissipating heat from the power element-embedded substrate being disposed on the first surface side of the wiring substrate.

### [Structure 4]

An electronic device including:
a module unit including a wiring substrate, and a power element-embedded substrate and a gate driver mounted on the wiring substrate; and a mounting substrate,
the module unit being longitudinally provided on the mounting substrate, the power element-embedded substrate being disposed on a first surface side of the wiring substrate, the gate driver being disposed on a second surface side of the wiring substrate opposite to the first surface side.

### [Structure 5]

The electronic device according to any one of [Structure 1] to [Structure 4], wherein the power element-embedded substrate includes a first wiring layer, a retention layer, an insulation layer located between the first wiring layer and the retention layer, and a power element, and the power element is embedded in the insulation layer.

### [Structure 6]

The electronic device according to [Structure 5], wherein the power element constitutes a portion of a power conversion circuit.

### [Structure 7]

The electronic device according to [Structure 1] or [Structure 2], further including a gate driver mounted on the wiring substrate.

### [Structure 8]

The electronic device according to [Structure 1] or [Structure 2], further including a driver unit including an other wiring substrate and a gate driver mounted on the other wiring substrate, wherein the driver unit is stacked on the module unit.

### [Structure 9]

The electronic device according to [Structure 2], further including a first gate driver on the first wiring substrate, and a second gate driver on the second wiring substrate.

### [Structure 10]

The electronic device according to [Structure 2], further including a driver unit including a third wiring substrate and a gate driver mounted on the third wiring substrate, wherein the driver unit is stacked on the first wiring substrate or the second wiring substrate.

### [Structure 11]

The electronic device according to any one of [Structure 1] to [Structure 10], wherein the heat dissipation member is connected to a cooler.

### [Structure 12]

The electronic device according to [Structure 2] or [Structure 4], wherein a heat dissipation member for thermally dissipating heat from the power element-embedded substrate is disposed on the power element-embedded substrate of the wiring substrate.

### REFERENCE SIGNS LIST

1a, 1b Wiring substrate
2a, 2b Power element-embedded substrate
3a, 3b Metal block (heat dissipation member)
3c Heat radiation fin (cooler)
3d Heat dissipation member
4a, 4b Insulating member
5a, 5b Recessed portion
6 Ground electrode
7a, 7b Gate driver
8a Connector
8b Connector insertion portion
11 Mounting substrate
12 Passive component
14a Resin portion
14b Pin portion
14c Pin portion
31a Power supply pin
31b Signal pin
32a Input pin
32b Output pin
32c GND pin
101a, 101b Transistor
102a, 102b Diode
111 First wiring layer (upper wiring layer)
112 Retention layer (second wiring layer/lower wiring layer)
115 Insulator
117 Electrical conduction via
118 Base material
119a Insulating protective layer
119b Insulating protective layer
120 Through hole
111a Adhesion layer (conductive adhesion layer)
111b Adhesion layer (conductive adhesion layer)

What is claimed is:

1. An electronic device comprising:
a module unit comprising a wiring substrate and a power element-embedded substrate mounted on the wiring substrate; and a mounting substrate,
the module unit being mounted on the mounting substrate so that the wiring substrate is parallel to or substantially parallel to the mounting substrate, a heat dissipation member for thermally dissipating heat from the power element-embedded substrate being disposed on the power element-embedded substrate side of the wiring substrate.

2. An electronic device comprising:
a first module unit comprising a first wiring substrate and a first power element-embedded substrate mounted on the first wiring substrate;
a second module unit comprising a second wiring substrate and a second power element-embedded substrate mounted on the second wiring substrate; and a mounting substrate,
the first module unit being mounted so that the first wiring substrate is parallel to or substantially parallel to the mounting substrate, the second module unit being stacked on the first module unit.

3. An electronic device comprising:
a module unit comprising a wiring substrate, and a power element-embedded substrate and a gate driver mounted on the wiring substrate; and a mounting substrate,
the module unit being longitudinally provided on the mounting substrate, the power element-embedded substrate and the gate driver being disposed on a first surface side of the wiring substrate, a heat dissipation member for thermally dissipating heat from the power element-embedded substrate being disposed on the first surface side of the wiring substrate.

4. An electronic device comprising:
a module unit comprising a wiring substrate, and a power element-embedded substrate and a gate driver mounted on the wiring substrate; and a mounting substrate,
the module unit being longitudinally provided on the mounting substrate, the power element-embedded substrate being disposed on a first surface side of the wiring substrate, the gate driver being disposed on a second surface side of the wiring substrate opposite to the first surface side.

5. The electronic device according to claim 1, wherein the power element-embedded substrate comprises a first wiring layer, a retention layer, an insulation layer located between the first wiring layer and the retention layer, and a power element, and the power element is embedded in the insulation layer.

6. The electronic device according to claim 5, wherein the power element constitutes a portion of a power conversion circuit.

7. The electronic device according to claim 1, further comprising a gate driver mounted on the wiring substrate.

8. The electronic device according to claim 1, further comprising a driver unit comprising an other wiring substrate and a gate driver mounted on the other wiring substrate, wherein the driver unit is stacked on the module unit.

9. The electronic device according to claim 2, further comprising a first gate driver on the first wiring substrate, and a second gate driver on the second wiring substrate.

10. The electronic device according to claim 2, further comprising a driver unit comprising a third wiring substrate and a gate driver mounted on the third wiring substrate, wherein the driver unit is stacked on the first wiring substrate or the second wiring substrate.

11. The electronic device according to claim 1, wherein the heat dissipation member is connected to a cooler.

12. The electronic device according to claim 4, wherein a heat dissipation member for thermally dissipating heat from the power element-embedded substrate is disposed on the power element-embedded substrate of the wiring substrate.
